(19) United States
(12) Patent Application Publication
(10) Pub. No.: US 2009/0316096 A1
(43) Pub. Date: Dec. 24, 2009

(54) MULTI-DOMAIN AND IPS LIQUID-CRYSTAL DISPLAY USING DRY ALIGNMENT

(76) Inventors: Alessandro Cesare Callegari, Yorktown Heights, NY (US); Praveen Chaudhari, Briarcliff Manor, NY (US); James Patrick Doyle, Bronx, NY (US); Eileen Galligan, Fishkill, NY (US); James Andrew Lacey, Mahopac, NY (US); Shui-Chih Alan Lien, Briarcliff Manor, NY (US)

Correspondence Address: Paul D. Greeley, Esq.;OHLANDT, GREELEY, RUGGIERO & PERLE, L.L.P., 10th FLOOR, ONE LANDMARK SQUARE, STAMFORD, CT, 06901-2682, US

(21) Appl. No.: 12/548,929

(22) Filed: Aug. 27, 2009

Related U.S. Application Data
(62) Division of application No. 09/597,780, filed on Jun. 20, 2000.

(51) Int. Cl. G02F 1/1337; C23C 14/04; G02F 1/13

(52) U.S. Cl. 349/125; 427/526; 349/187

(57) ABSTRACT

The present invention includes a method of preparing a dry deposited liquid-crystal alignment layer using one of a mechanical mask, photo-resist, UV treatment, and ridge and fringe field methods. The present invention further provides a multi-domain, wide viewing angle liquid-crystal display, comprising: a bottom substrate; a first transparent conductive layer; a top substrate; a color filter layer; a second transparent conductive layer; a first dry deposited liquid-crystal alignment layer; a second dry deposited liquid-crystal alignment layer, the second dry deposited liquid-crystal alignment layer being spaced adjacent to and facing the first dry deposited liquid-crystal alignment layer; spacers; and a liquid-crystal material. Each of the first alignment layer and the second alignment layer is divided into a plurality of pixels each having a boundary and at least two domains and the domains of each of the multi-domain, dry deposited liquid-crystal alignment layers is obtained by a method selected from the group consisting of: a mechanical mask, photo-resist, UV treatment, and ridge and fringe field. The multi-domain, wide viewing angle liquid-crystal display of the present invention can be operated in the in-plane switching mode, which results in reduced image sticking.

### CROSS-REFERENCED APPLICATIONS

This application is a divisional application of U.S. patent application Ser. No. 09/597,780, filed on Jun. 20, 2000, which is incorporated herein by reference in its entirety.

### BACKGROUND OF THE INVENTION

1. Field of the Invention

The present invention relates to multi-domain, wide viewing angle liquid-crystal display having a dry deposited liquid-crystal alignment layer. More particularly, the present invention relates to a method of preparing a dry deposited liquid-crystal alignment layer by one of mechanical mask, photo-resist, UV treatment and ridge and fringe field methods.

2. Description of the Prior Art

The use of a dry layer for liquid-crystal alignment is known. However, dry layer alignment alone does not provide a wide viewing angle for liquid-crystal display.

U.S. Pat. No. 6,020,946, the contents of which are incorporated herein by reference, describes a dry processing method for liquid-crystal displays using low energy ion bombardment. However, the liquid-crystal display produced by this method has a single domain structure and does not provide a wide viewing angle display.

U.S. Pat. No. 5,770,826, the contents of which are also incorporated herein by reference, describes a method of aligning liquid-crystals on a polyimide surface by exposing the surface to a low energy and neutral Argon ion beam. As in the previously incorporated U.S. Pat. No. 6,020,946, the liquid-crystal display produced by this method does not have a multi-domain structure and does not provide a wide viewing angle display. Accordingly, the present invention provides such a multi-domain, wide viewing angle liquid-crystal display.

### SUMMARY OF THE INVENTION

It is an object of the present invention to provide a method of preparing a dry deposited liquid-crystal alignment layer by one of mechanical mask, photo-resist, UV treatment, and ridge and fringe field methods.

It is another object of the present invention to provide a multi-domain, wide viewing angle liquid-crystal display.

It is still another object of the present invention to provide an improved method of preparing a multi-domain, wide viewing angle liquid-crystal display.

It is yet another object of the present invention to provide an improved method of preparing a multi-domain, wide viewing angle, in-plane switching mode liquid-crystal display.

It is a further object of the present invention to provide a multi-domain, wide viewing angle, in-plane switching mode liquid-crystal display.

It is a still further object of the present invention to provide low-cost, easily processed, multi-domain, wide viewing angle liquid-crystal display devices.

These and other objects of the present invention will become apparent by the novel multi-domain, wide viewing angle liquid-crystal displays, the methods of preparing the displays, and the methods of obtaining the dry deposited liquid-crystal alignment layer according to the present invention.

Accordingly, the present invention includes a method of preparing a dry deposited liquid-crystal alignment layer. The method of preparing a dry deposited liquid-crystal alignment layer is selected from one of mechanical mask, photo-resist, UV treatment, and ridge and fringe field methods.

The present invention further includes a multi-domain, wide viewing angle liquid-crystal display. The multi-domain, wide viewing angle liquid-crystal display comprises: a bottom substrate having a first surface; a first transparent conductive layer disposed over the first surface of the bottom substrate; a top substrate having a second surface; a color filter layer disposed over the second surface of the top substrate; a second transparent conductive layer disposed over the color filter layer; a first dry deposited liquid-crystal alignment layer over the first transparent conductive layer; a second dry deposited liquid-crystal alignment layer over the second transparent conductive layer; the second dry deposited liquid-crystal alignment layer being spaced adjacent to and facing the first dry deposited liquid-crystal alignment layer; a plurality of uniformly sized transparent or non-transparent spacers distributed within the space; and a liquid-crystal material disposed in the space therebetween. Each one of the first alignment layer and the second alignment layer is divided into a plurality of pixels each having a boundary and at least two domains. Each of the multi-domain, dry deposited liquid-crystal alignment layers is obtained by a method selected from one of mechanical mask, photo-resist, UV treatment, and ridge and fringe field.

The present invention also includes an improved method of preparing a liquid-crystal display. The method has the steps of forming a first dry deposited alignment layer, forming a second dry deposited alignment layer, spacing the first dry deposited alignment layer and the second dry deposited alignment layer adjacent to and facing each other and filling a liquid-crystal material in the space therebetween. The improvement comprises the steps of: forming a first multi-domain dry deposited alignment layer; forming a second multi-domain dry deposited alignment layer; spacing the first multi-domain dry deposited alignment layer and the second multi-domain dry deposited alignment layer adjacent to and facing each other; and filling a liquid-crystal material in the space therebetween. Each of the multi-domain, dry deposited liquid-crystal alignment layers is obtained by a method selected from one of mechanical mask, photo-resist, UV treatment, and ridge and fringe field methods.

The present invention further includes an improved method over the prior art methods of preparing an in-plane switching mode liquid-crystal display having the steps of forming a first polyimide alignment layer and a second polyimide alignment layer, wherein each of the first and second layers is rubbed with a mechanical roll wrapped in a velvet cloth. The improvement comprises the steps of: forming a first dry deposited alignment layer; forming a second dry deposited alignment layer; spacing the first dry deposited alignment layer and the second dry deposited alignment layer adjacent to and facing each other; and filling a liquid-crystal material in the space therebetween; wherein each of the dry deposited liquid-crystal alignment layers is obtained by one of: mechanical mask, photo-resist, UV treatment, and ridge and fringe field methods.

The present invention still further includes a wide viewing angle in-plane switching mode liquid-crystal display, comprising: a bottom polarizer; a bottom substrate; a top polarizer; a top substrate; a color filter layer disposed over the surface of the top substrate; a plurality of common electrodes disposed in the bottom substrate plane and a plurality of pixel electrodes disposed in a staggered relationship therewith to form a comb-like structure for producing an electric field parallel to the plane of the bottom substrate so that when operated, the molecules of the liquid-crystal material are switched to rotate in the substrate plane; a first dry deposited liquid-crystal alignment layer over the bottom substrate and the comb-like electrodes; a second dry deposited liquid-crystal alignment layer over the color filter layer; the second dry deposited liquid-crystal alignment layer being spaced adjacent to and facing the first dry deposited liquid-crystal alignment layer; a plurality of uniformly sized transparent or non-transparent spacers distributed within the space; and a liquid-crystal material disposed in the space therebetween.

The present invention provides a simple, cost effective and easily processed wide viewing angle liquid-crystal display.

### BRIEF DESCRIPTION OF THE DRAWINGS

FIG. 1 is a single pixel structure of a two-domain TN “twist nematic.”

FIG. 2 is a single pixel structure of a four-domain TN with left-handed chirality liquid-crystal, each domain tilting in a different direction.

FIG. 3 is a single pixel structure of a four-domain TN with left-handed chirality liquid-crystal, each domain tilting in a different direction.

FIG. 4 is a single pixel structure of a four-domain TN with non-chirality liquid-crystal, each domain tilting in a different direction.

FIG. 5 is a single pixel structures of a four-domain TN, with non-chirality liquid-crystal, each domain tilting in a different direction.

FIG. 6 shows different ways to arrange domains for the two-domain liquid-crystal displays.

FIG. 7 illustrates a UV treatment method with left-handed twist.

FIG. 8a illustrates an embodiment of the ridge and fringe field method.

FIG. 8b illustrates an embodiment of the ridge and fringe field method showing the rubbing direction on the top and bottom alignment layers.

FIG. 9 shows the contrast ratio contour as a function of viewing angle for a two domain panel fabricated using dry deposited alignment layer prepared by mechanical mask method.

FIG. 10 shows the contrast ratio contour as a function of viewing angle for a single domain panel fabricated using a conventional rubbed polyimide method.

FIG. 11a is a schematic of an in-plane switching (IPS) mode liquid-crystal display.

FIG. 11b is a schematic of common and pixel electrodes in a comb-like structure for an in-plane switching (IPS) mode liquid-crystal display.

FIG. 12 is a schematic of in-plane switching (IPS) electrodes showing liquid-crystal molecular orientation in the fully field-on state.

FIG. 13 is a schematic of a liquid-crystal display operating in a two domain in-plane switching (IPS) mode.

FIG. 14a is a schematic of alignment of the domains of a dry deposited layer by bombardment with an ion beam using discreet mechanical mask.

FIG. 14b is a schematic of alignment of the domains of a dry deposited layer by bombardment with an ion beam using a photoresist (PR) mask.

### DETAILED DESCRIPTION OF THE INVENTION

The present invention relates to the preparation of wide viewing angle liquid-crystal displays which use a dry layer as liquid-crystal alignment layer.

The wide viewing angle liquid-crystal display according to the present invention includes a method of preparing a dry deposited liquid-crystal alignment layer by one of the following methods:

(1) mechanical mask method;

(2) photo-resist method;

(3) UV treatment method; and

(4) ridge and fringe field method.

Each of the above methods employs one or more ion beam treatment step. For example, the ridge and fringe field method includes ion beam treatment step. Similarly, the UV treatment method includes ion beam treatment and UV treatment steps.

The mechanical mask method includes the steps of depositing on a substrate a material to form a transparent dry deposited alignment layer; masking the dry deposited layer into first domain areas and second domain areas of the dry deposited layer with a mask; and selectively bombarding the dry deposited layer with an ion beam through the mask.

Preferably, the first domain areas are unmasked and the entire layer is bombarded with an ion beam to produce the desired alignment in the entire area. Then, the first domain areas are masked and the second domain areas are unmasked and the entire layer is bombarded with an ion beam to produce the desired alignment in the second domain areas, the direction of the alignment in the second domain areas being different from the direction of the alignment in the second domain areas. Preferably, the mask is a mechanical mask, such as one made of a metal.

Preferably, the substrate is glass. Preferably, the conductive transparent layer is indium tin oxide (ITO) and the material dry deposited thereon is a material that can form an optically transparent layer, particularly in the visible spectrum.

Examples of materials suitable for use for dry depositing include hydrogenated diamond-like carbon (DLC), amorphous hydrogenated silicon, silicon carbide (SiC), silicon dioxide (SiO₂), glass, silicon nitride (Si₃N₄), alumina (Al₂O₃), cerium (IV) oxide (CeO₂), tin oxide (SnO₂), zinc titanate (ZnTiO₂) and other suitable dry materials. These materials can be used to form alignment layers which have, at a minimum, properties that are comparable to the properties exhibited by conventional polyimide films.

In accordance with the present invention, the alignment layer on the substrate is deposited by a dry deposition technique, using a suitable material, such as, diamond-like carbon.

Dry deposition of these materials is carried out by known methods, such as those described in the previously incorporated U.S. Pat. No. 6,020,946. For Example, a dry processed alignment layer is deposited onto a conductive transparent layer on a substrate, using a dry processing technique, such as plasma enhanced chemical vapor deposition (PECVD).

A hydrogenated diamond-like carbon alignment layer deposited in accordance with the preferred process used in the present invention is characterized as being amorphous, thermally stable, electrically insulating and optically transparent. Additionally, such alignment layers deposited from a hydrocarbon/helium gas mixture by PECVD have a dielectric strength comparable to that normally associated with diamond films. For example, the dry deposited layer may have a dielectric strength close to 10 MV/cm.

The ion beam alignment is carried out by known procedures, such as those described in the previously incorporated U.S. Pat. No. 6,020,946.

As is generally understood, the alignment layer serves to orient the direction of the liquid-crystal. That is, when a liquid-crystal cell is formed, the molecules of the liquid-crystal align along the direction(s) provided by the atomic structure of the alignment layers. Accordingly, an ion beam can be used to radiate ions at the alignment layer to disturb (i.e., to break bonds) and align the atomic structure of the alignment layer in a desired direction or orientation, such as in a horizontal, unidirectional or multidirectional manner.

In one embodiment, a mask with features etched into it can also be used to selectively align a local area, thus leading to the fabrication of domains of alignment. These can then be used to fabricate a multidomain display, which has vastly superior viewing attributes. For multidirectional alignment, it is preferred that the multidirections are selected in such a fashion that results in a multidomain device.

The orientation or direction of the alignment layer can be adjusted by selecting, for example, an appropriate angle of incidence θ (theta), voltage applied to the ion beam source for ion extraction and the amount of exposure time. The alignment layer is preferably exposed to the aligning ion radiation from about 5 seconds to 2 minutes for a typical diamond-like carbon alignment layer.

Thus, the dry processed alignment layer is irradiated with a beam of atoms, i.e., ion beam bombardment, to arrange the atomic structure of the alignment layer in at least one desired direction in order to orient the liquid-crystal molecules.

The source of ion beam can be argon, nitrogen, oxygen, or another gas or mixture of gases.

The various embodiments of the mechanical mask method are shown in FIG. 1 to 5.

Referring to FIG. 1, a single pixel structure of a two-domain TN, “twist nematic,” is seen. The heavy dashed lines represent the pixel boundary on the first dry deposited layer, i.e., the bottom dry deposited layer, with domain #1 and domain #2. The light dashed line represents the domain boundary on the first dry deposited layer, i.e., bottom dry deposited layer, with domain #1 and domain #2.

The ion beam bombards the dry deposited layer from a direction which makes an angle with the substrate normal. The light dashed arrow represents the projection of the ion bombardment vector, which is formed by the direction of ion beam bombardment pointing from ion beam source to the dry deposited layer onto the bottom dry deposited layer plane. The bombardment of the ion beam with a proper incident angle, energy and time results in a good alignment and proper pretilt angle for the liquid-crystal material.

The pretilt directions of the liquid-crystal follow the rubbing treatment direction of mechanical rubbing on the polyimide film in cases when polyimide film is used. But for the ion beam treatment on the dry layer, the pretilt direction is opposite to the direction of the rubbing treatment.

Referring again to FIG. 1, a pixel that is divided into two domains can be seen. The direction of the ion bombardment in each domain on the bottom dry deposited layer is different.

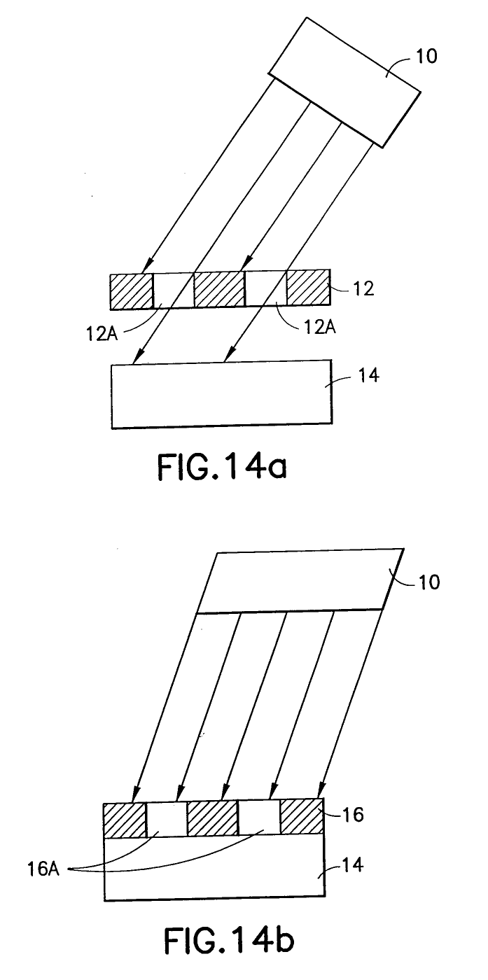

Referring to FIG. 14a, a discreet mechanical mask 12, having one or more openings 12A, is placed between ion beam source 10 and the dry deposited layer 14. The mechanical mask can be placed in contact with, directly above, or at a distance away from the dry deposited layer 14. In the embodiment shown, the mechanical mask is placed at a distance away from the dry deposited layer 14. The dry deposited layer is aligned by bombardment from the ion beam source 10. The direction of the ion beam bombardment is depicted by the arrows.

FIG. 14b, shows a photoresist (PR) layer 16, having one or more openings 16A, placed directly above the dry deposited layer 14. The dry deposited layer is aligned by bombardment from the ion beam source 10. The arrows depict the direction of the ion beam bombardment.

When one area of the pixel in FIG. 1 is bombarded, other areas are covered by a mask, such as a mechanical mask (FIG. 14a) or a photo-resist mask (FIG. 14b). However, the first bombardment can be done either with or without a mask since, if no mask is used, the direction of the second bombardment will overwrite the first bombardment direction.

The heavy solid lines in FIG. 1 represent the pixel boundary on the second dry deposited layer, i.e., the top dry deposited layer. The light solid line represents the domain boundary on the second dry deposited layer (top dry deposited layer). The solid arrow represents the projection of ion beam bombardment vector onto the second (top) dry deposited layer plane. The dashed arrow represents the projection of ion beam bombardment vector onto the first (bottom) dry deposited layer plane.

The direction of the ion bombardment in each domain on the second (top) dry deposited layer is also different. With the ion beam treatment on both the bottom and top dry deposited layers, a two-domain TN “twist nematic” panel will be formed after the panel is filled with left-handed chirality liquid-crystal.

If right-handed chirality liquid-crystal is used, the ion beam bombardment direction should be changed accordingly.

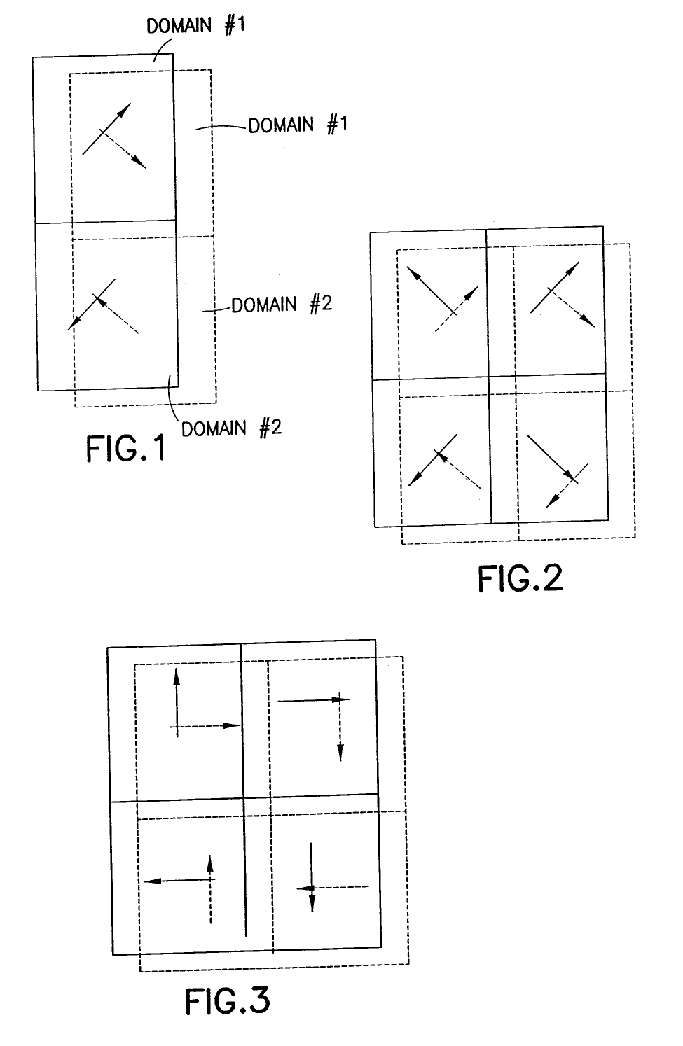

FIG. 2 to 5 show single pixel structures for a four-domain TN. The conventions for line and arrows are the same as those in FIG. 1. The basic concept in FIG. 2 to 5 is the same as that of FIG. 1, except that instead of a pixel being divided into two domains, a pixel is divided into four domains.

In FIGS. 2 and 3, left-handed chirality liquid-crystal is used, so that all four domains are left-handed twist, with each domain tilting in a different direction.

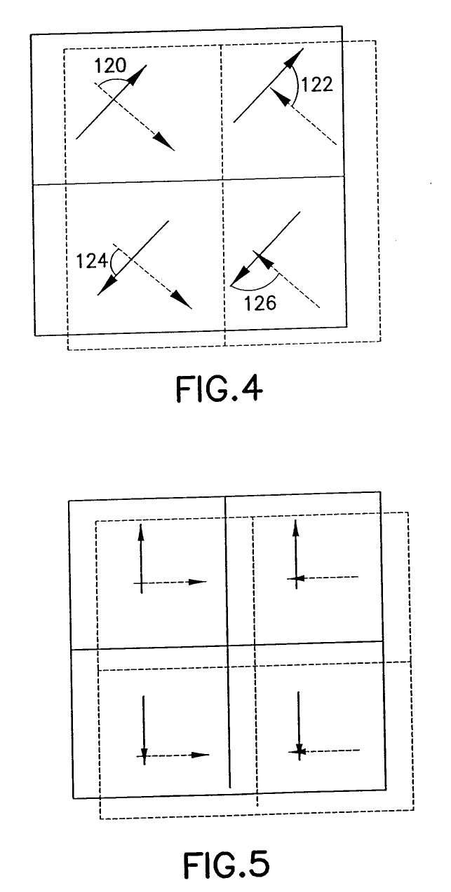

In FIGS. 4 and 5, a non-chirality liquid-crystal is used. Due to the arrangement of the alignment directions for each domain, two domains are left-handed twist and other two domains are right-handed twist.

In FIGS. 2 and 3, each dry deposited layer requires four ion beam treatments. In FIGS. 4 and 5, each dry deposited layer requires only two ion beam treatments. Thus, for the first ion beam treatment a mechanical mask is not necessary. However, a mechanical mask is needed for any ion beam treatment other than the first ion beam treatment, since the second ion beam treatment will overwrite the first ion beam treatment.

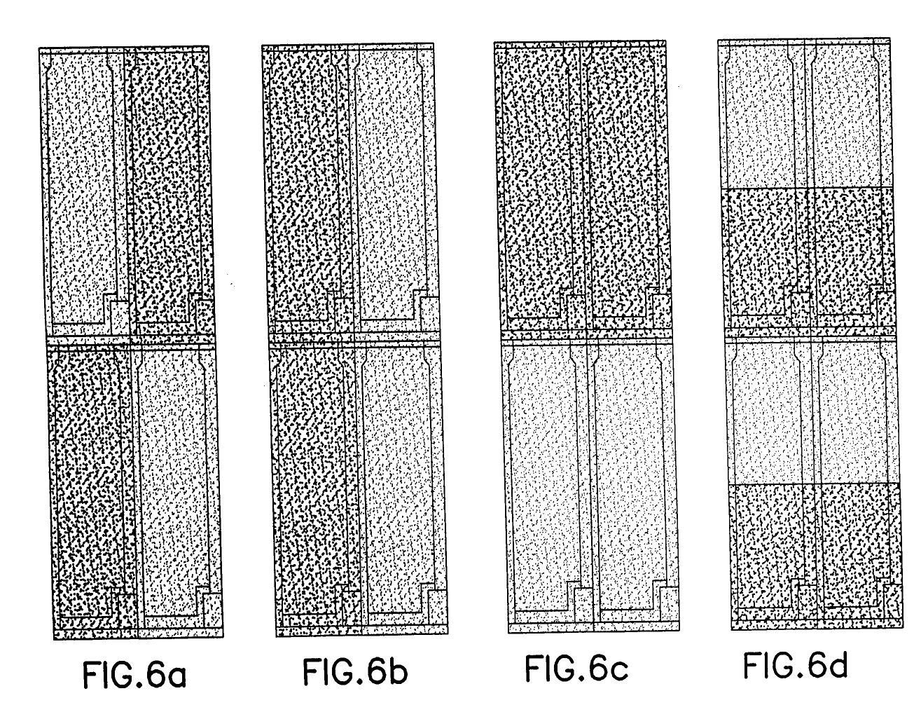

FIG. 6 shows different ways to arrange domains for the two-domain liquid-crystal displays. From left to right, designs (a), (b) and (c) show arrangement of two domains in adjacent pixels with a single-domain within each pixel. Embodiment 6d on the far right depicts an arrangement of two domains within a pixel.

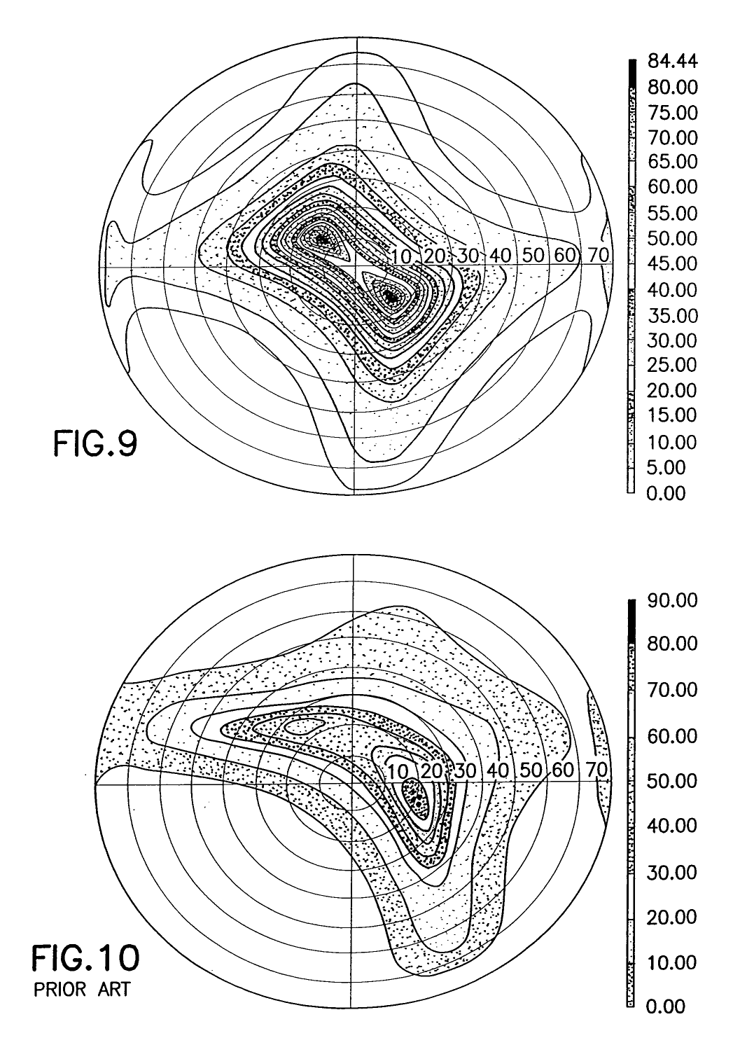

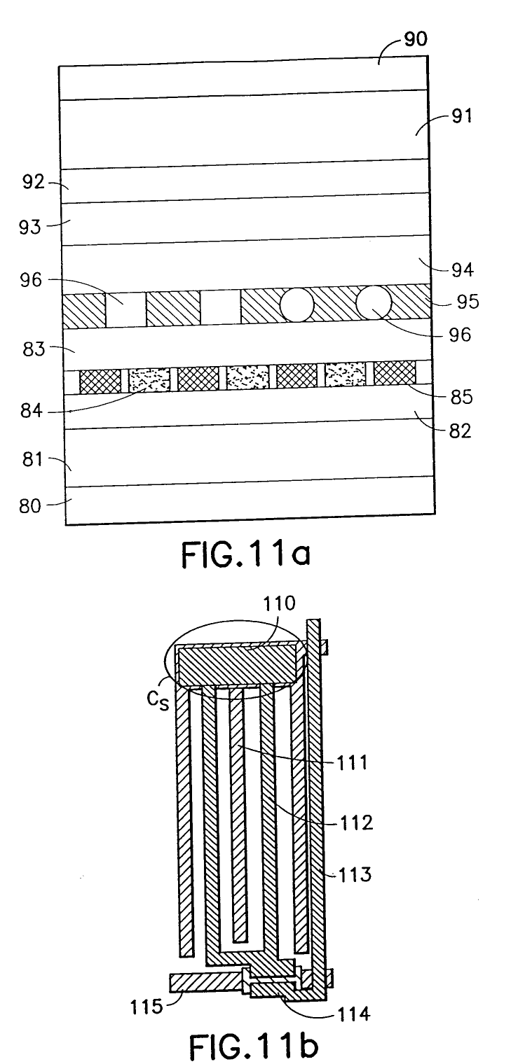

FIG. 9 shows the contrast ratio contour as a function of viewing angle for a two domain panel fabricated using dry deposited alignment layer prepared by the mechanical mask method of the present invention. FIG. 10 shows the contrast ratio contour as a function of viewing angle for a single domain panel fabricated using a conventional rubbed polyimide method. This demonstrates that the two domain liquid crystal display according to the present invention has a wider and more symmetric viewing angle than the single domain liquid crystal display.

The photo-resist method includes the steps of: depositing on a conductive layer on a substrate a material to form a dry deposited layer; partitioning the dry deposited layer into first domain areas and second domain areas of the dry deposited layer; bombarding the dry deposited layer with a first ion beam without a mask; thereafter covering the first domain areas of the dry deposited layer with a mask leaving the second domain areas open; bombarding the second domain areas with a second ion beam; and removing the mask.

The photo-resist method may further include: repeating the covering and removing steps as needed.

Preferably, the step of partitioning comprises the step of covering only the first domain areas with a mask, and the step of covering comprises the step of applying a layer of photo-resist.

The various embodiments of the photo-resist method are similar to those of the mechanical mask method, with the exception that the mechanical mask is replaced by the photo-resist layer.

The alignment layers on the substrates are first deposited with a dry alignment material, such as diamond-like carbon, silicon dioxide, or other suitable dry materials. Then they are treated with an ion beam bombardments. As before, the source of ion beam can be argon, nitrogen, oxygen, or another gas or mixture of gases.

The first domain areas are covered by the photo-resist layer and the second domain areas are left uncovered. This can be easily accomplished by a conventional photolithographic process. The dry deposited layers then receive a second ion beam treatment. After that, the photo-resist layer is removed, i.e., stripped off. This process is repeated as needed to create the desired domains. Two corresponding dry deposited alignment layers are then assembled together and a liquid-crystal is filled to the cell to form the multi-domain liquid-crystal display panels with dry alignment layers.

The UV treatment method includes the steps of: depositing on a conductive layer on a substrate a material to form a dry deposited alignment layer; partitioning the dry deposited layer into first domain areas and second domain areas of the dry deposited layer; selectively exposing one of the first and the second domain areas to UV light; and bombarding both the first and the second domain areas with an ion beam in a single direction to produce in the non-UV exposed domain areas a pretilt angle different from the areas that were exposed to UV light.

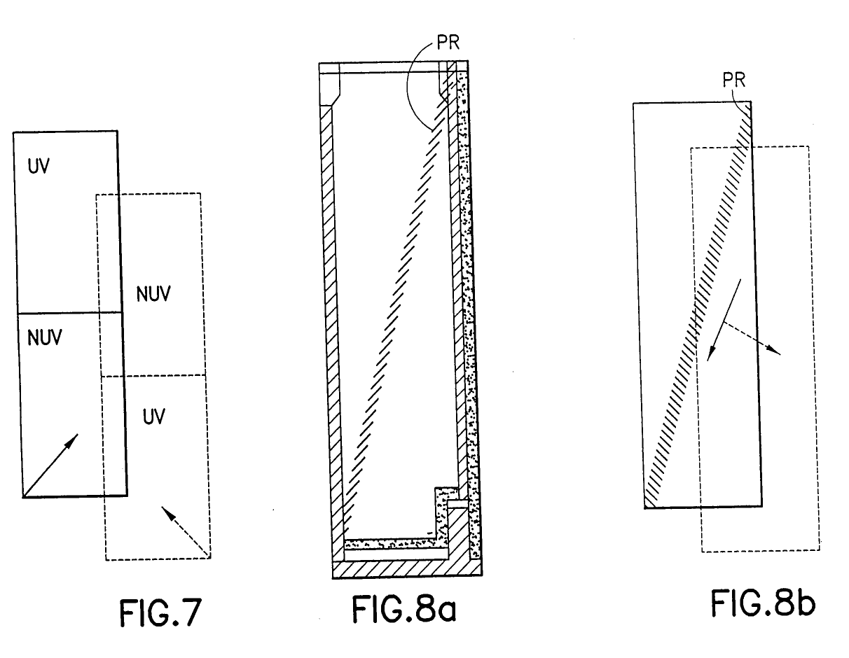

One embodiment of the UV treatment method, which is exemplified using left-handed twist, is illustrated in FIG. 7. The conventions for line and arrows are the same as those used for FIG. 1.

The conductive layers on the substrates are first coated with a dry deposited layer for alignment. The dry deposited layers are then exposed to UV light with a photo or mechanical mask so that the areas which are labeled UV are exposed to UV light, and the areas which labeled NUV are not exposed to UV light. The areas are then treated with ion beam bombardments. The entire dry deposited layer is bombarded by ion beam in a single direction, and no mask is required for ion beam treatment. Because the areas exposed to the UV light have a pretilt angle different from the areas that are not treated with UV light, the combination of the UV treatment and the ion beam treatment produces a two-domain TN “twist nematic.” The top and bottom layers are then assembled to define a cell, which is then filled with left-handed twist liquid crystal.

The order of ion beam bombardment and UV light exposure may be interchanged. Thus, one of the first and second domain areas is selectively bombarded with an ion beam in a single direction; and thereafter, both first and second domain areas are exposed to UV light to produce in the non-bombarded domain areas a pretilt angle different from the areas that were bombarded with an ion beam.

Suitable UV wavelengths are in the range of about 180 nm to 320 nm, and suitable exposure times are about 2 seconds to 30 minutes.

The ridge and fringe field method includes the steps of: providing a top substrate having a surface; providing a color filter on the top substrate; providing a transparent conductive layer disposed over the color filter; building a polymer ridge on the transparent conductive layer on the color filter side; depositing on the surface of the transparent conductive layer a material to form a dry deposited alignment layer; and bombarding the dry deposited layer with an ion beam under conditions to produce a low pretilt angle.

One embodiment of the ridge and fringe field method is shown in FIG. 8a. FIG. 8b illustrates an embodiment of the ridge and fringe field method showing the tilt on the top and bottom alignment layers.

A polymer ridge (PR), which is a polymer wall for defining two or more regions, is built on top of the transparent conductive layer, such as, indium tin oxide (ITO) or an equivalent, on the color filter side.

Preferably, the ridge width is from about 2 μm to about 15 μm. Preferably, the ridge height is from about ⅓ of cell gap to about ⅔ of cell gap. Preferably, the slope of the ridge is from about 20 degrees to about 80 degrees.

The bottom layer has no polymer ridge or color filter, but has a transparent conductive layer, such as, indium tin oxide (ITO) or an equivalent. The dry deposited alignment layers are then bombarded with an ion beam under conditions that produce a low pretilt angle.

The bombardment direction is as shown in FIG. 8b. Each dry deposited alignment layer receives a single ion beam treatment only.

The top and bottom layers are then assembled to define a cell, which is then filled with left-handed twist liquid-crystal. This will form a two domain TN “twist nematic” cell with a dry alignment layer.

The present invention further includes a multi-domain, wide viewing angle liquid-crystal display.

In this embodiment, as before, the multi-domain, wide viewing angle liquid-crystal display includes a bottom substrate, a first transparent conductive layer, a top substrate, a color filter layer, a second transparent conductive layer, a first dry deposited liquid-crystal alignment layer, a second dry deposited liquid-crystal alignment layer adjacent to and facing the first dry deposited liquid-crystal alignment layer; uniformly sized transparent or non-transparent spacers distributed therebetween; and a liquid-crystal material in the space between the dry deposited alignment layers. Each of the first alignment layer and the second alignment layer is divided into a plurality of pixels each having a boundary and at least two domains. Each of the multi-domain, dry deposited liquid-crystal alignment layers is obtained by one of the following methods: mechanical mask, photo-resist, UV treatment, and ridge and fringe field methods.

Preferably, the ion beam is provided from a source such as one containing argon, nitrogen, oxygen, and a mixture thereof.

In one embodiment, each of the pixels have a first domain and a second domain, with the first domain and second domain having different ion bombardment directions.

Preferably, the liquid-crystal material is selected from a liquid-crystal having left-handed chirality, a liquid-crystal having right-handed chirality, and a liquid-crystal having no chirality.

Preferably, the transparent conductive layer comprises indium tin oxide.

The improved method of preparing a liquid-crystal display according to the present invention comprises the steps of forming a first multi-domain dry deposited alignment layer, forming a second multi-domain dry deposited alignment layer, spacing the first and second multi-domain dry deposited alignment layers adjacent to and facing each other, and filling a liquid-crystal material in the space between the alignment layers.

As discussed above, each of the multi-domain, dry deposited liquid-crystal layers is obtained by one of mechanical mask, photo-resist, UV treatment, and ridge and fringe field methods.

The present invention still further includes an improved method of preparing an in-plane switching mode liquid-crystal display. Generally, in displays of this type a first and a second polyimide alignment layers are formed. The layers are then rubbed with a mechanical roll wrapped in a velvet cloth. The present improvement comprises forming a first dry deposited alignment layer, forming a second dry deposited alignment layer, spacing the first and second multi-domain dry deposited alignment layers adjacent to and facing each other and filling a liquid-crystal material in the space between the alignment layers. The first and second dry deposited alignment layers in the improved method of preparing the in-plane switching mode liquid-crystal display of the present invention can also be multi-domain dry deposited alignment layers.

Referring to FIG. 11a, schematic of a multi-domain, wide viewing angle in-plane switching (IPS) mode liquid-crystal display is seen.

The in-plane switching mode liquid-crystal display comprises bottom polarizer 80, bottom substrate 81, first transparent (or non-transparent) conductive layer 82, a top polarizer 90, a top substrate 91, a color filter layer 92, a second transparent conductive layer 93, a plurality of common electrodes 84 disposed in the bottom substrate plane and a plurality of pixel electrodes 85 disposed in a staggering relationship therewith to form a comb-like structure, a first dry deposited liquid-crystal alignment layer 83, a second dry deposited liquid-crystal alignment layer 94 being spaced adjacent to and facing the first dry deposited liquid-crystal alignment layer 83, a plurality of uniformly sized transparent or non-transparent spacers 96 distributed within the space, a liquid-crystal material 95 disposed in the space between the alignment layers. The spacers can be pearl or post shaped.

Preferably, dry deposited liquid-crystal alignment is obtained by treating a dry deposited layer with an ion beam in a direction making from about 10 to about 20 degree angle with the plane of the electrodes.

Referring to FIG. 11b, the common and pixel electrodes 111 and 112, respectively, can be seen to be arranged in a comb-like structure for an in-plane switching (IPS) mode liquid-crystal display.

Each common electrode 111 on one end is in communication with storage capacitor 110. Each pixel electrode 112 is in communication on one end with the storage capacitor 110 and on the other end with thin film transistor 114. The thin film transistor 114 is in communication with data bus line 113 and gate bus line 115 and is selectively activated thereby, for turning the associated pixel on and off.

The described arrangement of the common and pixel electrodes produces an electric field that is vertical to the plane of the bottom substrate so that when operated, the molecules of the liquid-crystal material are switched to rotate in the plane by the electric field that is parallel to the substrate plane.

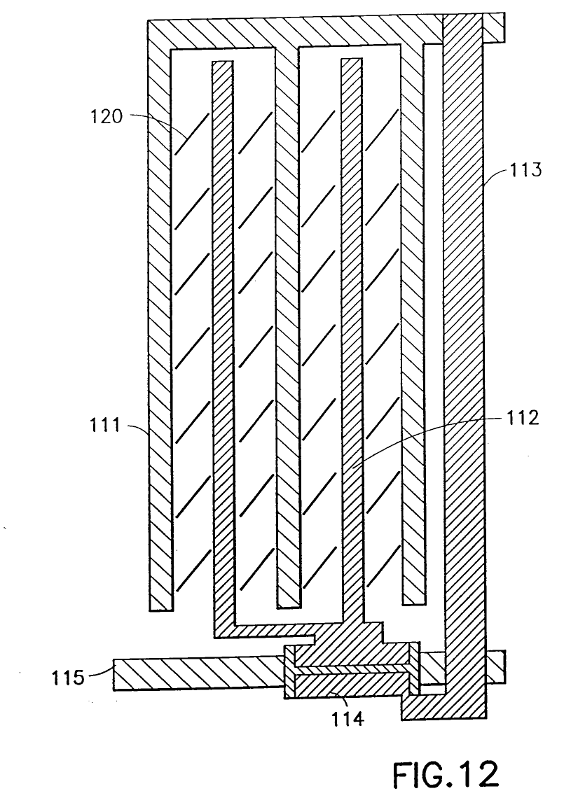

FIG. 12 shows a schematic of in-plane switching (IPS) electrodes, with common electrodes 111, pixel electrodes 112, thin film transistor 114, data bus line 113 and gate bus line 115 in view. The rods 120 show liquid-crystal molecular orientation in the fully field-on state.

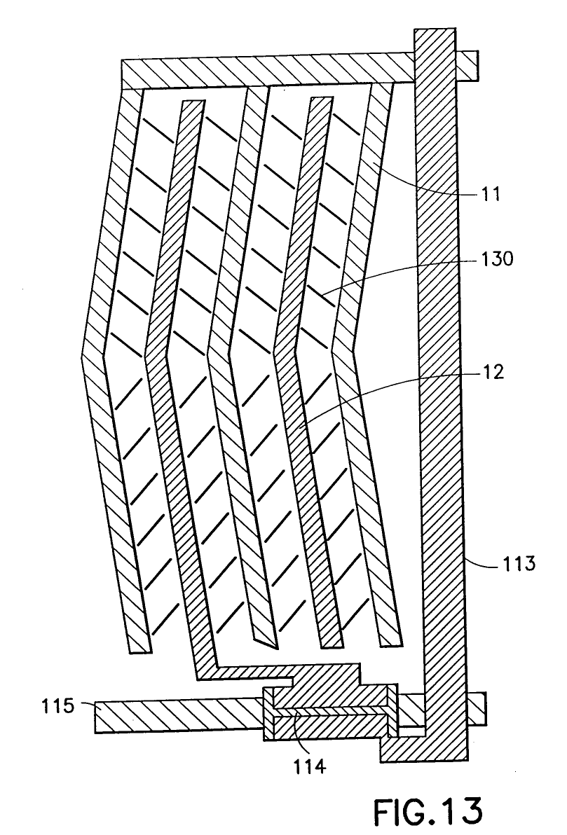

FIG. 13 shows a schematic of a liquid-crystal display operating in a two domain in-plane switching (IPS) mode, with common electrodes 111, pixel electrodes 112, thin film transistor 114, data bus line 113 and gate bus line 115 in view. The rods 130 show liquid-crystal molecular orientation in the fully field-on state.

The present invention thus provides a simple, cost effective and easily processed wide viewing angle liquid-crystal display.

The multi-domain, wide viewing angle liquid-crystal display according to the present invention has utility in a wide variety of high contrast, low power visual display applications.

Although discussed in the context of selectively masking the output of ion beam source, in some embodiments a direct writing technique can be used to direct the ion beam to desired regions to form the domains.

The present invention has been described with particular reference to the preferred embodiments. It should be understood that variations and modifications thereof can be devised by those skilled in the art without departing from the spirit and scope of the present invention. Accordingly, the present invention embraces all such alternatives, modifications and variations that fall within the scope of the appended claims.

What is claimed is:

1. A method of preparing a multi-domain, dry deposited liquid-crystal alignment layer, wherein said method is selected from the group consisting of: mechanical mask, photo-resist, UV treatment, and ridge and fringe field.

2. The method of claim 1, wherein said mechanical mask method comprises:
depositing on a transparent conductive layer on a substrate a material to form a dry deposited layer;
masking said dry deposited layer into first domain areas and second domain areas of the dry deposited layer with a mask; and
selectively bombarding said dry deposited layer with an ion beam through said mask.

3. The method of claim 2, wherein said material is selected from the group consisting of: hydrogenated diamond-like carbon, amorphous hydrogenated silicon, silicon carbide (SiC), silicon dioxide (SiO₂), glass, silicon nitride (Si₃N₄), alumina (Al₂O₃), cerium (IV) oxide (CeO₂), tin oxide (SnO₂), zinc titanate (ZnTiO₂) and a combination thereof.

4. The method of claim 1, wherein said photo-resist method comprises:
depositing on a transparent conductive layer on a substrate a material to form a dry deposited layer;
partitioning said dry deposited layer into first domain areas and second domain areas of the dry deposited layer;
bombarding said dry deposited layer with a first ion beam; thereafter
covering said first domain areas of said dry deposited layer with a mask leaving said second domain areas open;
bombarding said second domain areas with a second ion beam; and
removing said mask.

5. The method of claim 4, wherein said step of partitioning comprises the step of covering only said first domain areas with a mask.

6. The method of claim 5, wherein said step of covering comprises the step of applying a layer of photo-resist.

7. The method of claim 1, wherein said UV treatment method comprises:
depositing on a transparent conductive layer on a substrate a material to form a dry deposited layer;
partitioning said dry deposited layer into first domain areas and second domain areas of the dry deposited layer;
selectively exposing one of said first and said second domain areas to UV light; and
bombarding both said first and said second domain areas with an ion beam in a single direction to produce in non-UV exposed domain areas a pretilt angle different from the areas that were exposed to UV light.

8. The method of claim 1, wherein said ridge and fringe field method comprises:
providing a top substrate having a surface;
providing a color filter on said top substrate;
providing a transparent conductive layer disposed over said color filter;
building a polymer ridge on said transparent conductive layer on the color filter side;
depositing on said surface of said transparent conductive layer and said ridge a material to form a dry deposited alignment layer; and
bombarding said dry deposited layer with an ion beam under conditions to produce a low pretilt angle.

9. A multi-domain, wide viewing angle liquid-crystal display, comprising:
a bottom substrate having a first surface;
a first transparent conductive layer disposed over said first surface of said bottom substrate;
a top substrate having a second surface;
a color filter layer disposed over said second surface of said top substrate;
a second transparent conductive layer disposed over said color filter;
a first dry deposited liquid-crystal alignment layer over said first transparent conductive layer;
a second dry deposited liquid-crystal alignment layer over said second transparent conductive layer; said second dry deposited liquid-crystal alignment layer being spaced adjacent to and facing said first dry deposited liquid-crystal alignment layer;
a plurality of uniformly sized transparent or non-transparent spacers distributed within said space; and
a liquid-crystal material disposed in the space therebetween;
wherein each of said first alignment layer and said second alignment layer is divided into a plurality of pixels each having a boundary and at least two domains; and wherein each of said multi-domain, dry deposited liquid-crystal alignment layers is obtained by a method selected from the group consisting of: mechanical mask, photo-resist, UV treatment, and ridge and fringe field methods,
wherein said domains of said first and said second dry deposited liquid-crystal alignment layers are obtained by photo-resist method.

10. The multi-domain, wide viewing angle liquid-crystal display of claim 9, wherein each of said pixels have a first domain and a second domain.

11. The multi-domain, wide viewing angle liquid-crystal display of claim 9, wherein said photo-resist method comprises:
depositing on a transparent conductive layer on a substrate a material to form a dry deposited layer;
partitioning said dry deposited layer into first domain areas and second domain areas of the dry deposited layer;
bombarding said dry deposited layer with a first ion beam; thereafter
covering said first domain areas of said dry deposited layer with a mask leaving said second domain areas open;
bombarding said second domain areas with a second ion beam; and
removing said mask.

12. The multi-domain, wide viewing angle liquid-crystal display of claim 11, further comprising:
repeating the steps as needed.

13. A multi-domain, wide viewing angle liquid-crystal display, comprising:
a bottom substrate having a first surface;
a first transparent conductive layer disposed over said first surface of said bottom substrate;
a top substrate having a second surface;
a color filter layer disposed over said second surface of said top substrate;
a second transparent conductive layer disposed over said color filter;
a first dry deposited liquid-crystal alignment layer over said first transparent conductive layer;
a second dry deposited liquid-crystal alignment layer over said second transparent conductive layer; said second dry deposited liquid-crystal alignment layer being spaced adjacent to and facing said first dry deposited liquid-crystal alignment layer;
a plurality of uniformly sized transparent or non-transparent spacers distributed within said space; and
a liquid-crystal material disposed in the space therebetween;
wherein each of said first alignment layer and said second alignment layer is divided into a plurality of pixels each having a boundary and at least two domains; and wherein each of said multi-domain, dry deposited liquid-crystal alignment layers is obtained by a method selected from the group consisting of: mechanical mask, photo-resist, UV treatment, and ridge and fringe field methods,
wherein said domains of said first and said second dry deposited liquid-crystal alignment layers are obtained by said UV treatment method.

14. The multi-domain, wide viewing angle liquid-crystal display of claim 13, wherein each of said pixels have a first domain and a second domain.

15. The multi-domain, wide viewing angle liquid-crystal display of claim 13, wherein said UV treatment method comprises:
depositing on a transparent conductive layer on a substrate a material to form a dry deposited layer;
partitioning said dry deposited layer into first domain areas and second domain areas of the dry deposited layer;
selectively exposing one of said first and said second domain areas to UV light; and
bombarding both said first and said second domain areas with an ion beam in a single direction to produce in said non-UV exposed domain areas a pretilt angle different from the areas that were exposed to UV light.

16. The multi-domain, wide viewing angle liquid-crystal display of claim 13, wherein said UV treatment method comprises:
depositing on a transparent conductive layer on a substrate a material to form a dry deposited layer;
partitioning said dry deposited layer into first domain areas and second domain areas of the dry deposited layer;
selectively bombarding one of said first and said second domain areas with an ion beam in a single direction; and
exposing both said first and said second domain areas to UV light to produce in said non-bombarded domain areas a pretilt angle different from the areas that were bombarded with an ion beam.

17. A multi-domain, wide viewing angle liquid-crystal display, comprising:
a bottom substrate having a first surface;
a first transparent conductive layer disposed over said first surface of said bottom substrate;
a top substrate having a second surface;
a color filter layer disposed over said second surface of said top substrate;
a second transparent conductive layer disposed over said color filter;
a first dry deposited liquid-crystal alignment layer over said first transparent conductive layer;
a second dry deposited liquid-crystal alignment layer over said second transparent conductive layer; said second dry deposited liquid-crystal alignment layer being spaced adjacent to and facing said first dry deposited liquid-crystal alignment layer;
a plurality of uniformly sized transparent or non-transparent spacers distributed within said space; and
a liquid-crystal material disposed in the space therebetween;
wherein each of said first alignment layer and said second alignment layer is divided into a plurality of pixels each having a boundary and at least two domains; and wherein each of said multi-domain, dry deposited liquid-crystal alignment layers is obtained by a method selected from the group consisting of: mechanical mask, photo-resist, UV treatment, and ridge and fringe field methods,
wherein said domains of said first and said second dry deposited liquid-crystal alignment layers are obtained by said ridge and fringe field method.

18. The multi-domain, wide viewing angle liquid-crystal display of claim 17, wherein said ridge and fringe field method comprises:
building a polymer ridge on said transparent conductive layer on the color filter side;
depositing on said surface of said transparent conductive layer a material to form a dry deposited layer; and
bombarding said dry deposited layer with an ion beam under conditions to produce a low pretilt angle.

19. The multi-domain, wide viewing angle liquid-crystal display of claim 18, wherein said transparent conductive layer comprises indium tin oxide.

20. An improved method of preparing a liquid-crystal display of the type having the steps of forming a first dry deposited alignment layer, forming a second dry deposited alignment layer, spacing the first dry deposited alignment layer and the second dry deposited alignment layer adjacent to and facing each other and filling a liquid-crystal material in the space therebetween, wherein the improvement comprises the steps of:
forming a first multi-domain dry deposited alignment layer;
forming a second multi-domain dry deposited alignment layer;
spacing said first multi-domain dry deposited alignment layer and said second multi-domain dry deposited alignment layer adjacent to and facing each other; and
filling a liquid-crystal material in the space therebetween;
wherein each of said multi-domain, dry deposited liquid-crystal alignment layers is obtained by a method selected from the group consisting of: mechanical mask, photo-resist, UV treatment, and ridge and fringe field.

21. An improved method of preparing an in-plane switching mode liquid-crystal display of the type having the steps of forming a first polyimide alignment layer and a second polyimide alignment layer, wherein each of the first and second layers is rubbed with a mechanical roll wrapped in a velvet cloth, wherein the improvement comprises the steps of:
forming a first dry deposited alignment layer;
forming a second dry deposited alignment layer;
spacing said first dry deposited alignment layer and said second dry deposited alignment layer adjacent to and facing each other; and
filling a liquid-crystal material in the space therebetween;
wherein each of said dry deposited liquid-crystal alignment layers is obtained by a method selected from the group consisting of: mechanical mask, photo-resist, UV treatment, and ridge and fringe field.
